(19) United States
(12) Patent Application Publication
(10) Pub. No.: US 2026/0068651 A1
(43) Pub. Date: Mar. 5, 2026

(54) SEMICONDUCTOR DEVICE INCLUDING FUSES AND MANUFACTURING METHOD OF THE SAME

(71) Applicant: NANYA TECHNOLOGY CORPORATION, NEW TAIPEI CITY (TW)

(72) Inventor: HSIH-YANG CHIU, NEW TAIPEI CITY (TW)

(21) Appl. No.: 18/883,948

(22) Filed: Sep. 12, 2024

Related U.S. Application Data
(62) Division of application No. 18/816,126, filed on Aug. 27, 2024.

(51) Int. Cl. H01L 23/525

(52) U.S. Cl. CPC H01L 23/5256

(57) ABSTRACT

A semiconductor device and method for manufacturing the same are provided. The semiconductor device includes a substrate, a lower supporting frame; an upper supporting frame, and a capacitor component. The lower supporting frame is disposed over the substrate. The upper supporting frame is disposed over and spaced apart from the lower supporting frame. The capacitor component is disposed over the substrate. The capacitor component includes a lower electrode having a noncontinuous sidewall abutting the lower supporting frame.

### CROSS-REFERENCE TO RELATED APPLICATION

This application is a divisional application of U.S. Non-Provisional application Ser. No. 18/816,126 filed Aug. 27, 2024, which is incorporated herein by reference in its entirety.

### TECHNICAL FIELD

The present disclosure relates to a semiconductor device and method for manufacturing the same, and more particularly, to a semiconductor device including fuse metals and method for manufacturing the same.

### DISCUSSION OF THE BACKGROUND

With integrated circuits (ICs) achieving regular increases in performance and miniaturization, advances in materials and design produce successive generations with smaller and more complex memory devices.

As the semiconductor industry develops, detecting failure after assembly is becoming much more important for the memory device. Weak bits may occur to affect the functional and performance of the memory device. However, it may be difficult to obtain the high voltage for burning or blowing out the fuse, since the memory device may have been assembled and mounted on a printed circuit board. Accordingly, it becomes inconvenient to implement the testing and repairing for the memory device. Therefore, a new semiconductor device and method of improving such problems is required.

This discussion of the Background section is provided for background information only. The statements in this discussion of the Background are not an admission that the subject matter disclosed herein constitutes prior art with respect to the present disclosure, and no part of this discussion of the background may be used as an admission that any part of this application constitutes prior art with respect to the present disclosure.

### SUMMARY

One aspect of the present disclosure provides a semiconductor device. The semiconductor device includes a doped structure, a first dielectric layer, a second dielectric layer and a first insulating structure. The first dielectric layer extends along a first direction and is disposed on a top surface of the doped structure along a second direction vertical to the first direction. The second dielectric layer is provided below a bottom surface of the doped structure along the second direction. The first insulating structure extends along the second direction and disposed adjacent to a lateral surface of the doped structure. A first end of the first insulating structure is at the same escalation level with the bottom surface of the doped structure, and length of the first insulating structure is smaller than length of the doped structure.

Another aspect of the present disclosure provides a semiconductor device. The semiconductor device includes a fuse metal, a doped structure, a first dielectric layer, a second dielectric layer and two doped portions. The first dielectric layer extends along a first direction and disposed above the fuse metal. The first dielectric layer comprises a first recess structure for accommodating the fuse metal. The doped structure is formed above the first dielectric layer and extends along a second direction vertical to the first direction. The second dielectric layer extends along the first direction and is disposed above the doped structure. The doped portions are adjacent to two lateral surfaces of the doped structure, and the doped portions are spaced apart from the first dielectric layer and the second dielectric layer.

Another aspect of the present disclosure provides a method of manufacturing a semiconductor device. The method includes: forming an insulating structure along a lateral side of a recess area of a well region; forming a doped structure covering the insulating structure, wherein the doped structure is longer than the insulating structure, and the insulating structure is between the well region and the doped structure; forming a doped portion external to the doped structure and adjacent to the insulating structure and the doped structure; forming a first dielectric layer above the doped structure; forming a second dielectric layer below the doped structure, wherein the doped portion is between and spaced apart from the first dielectric layer and the second dielectric layer; and forming a fuse metal below the second dielectric layer.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device, in accordance with some embodiments of the present disclosure.

FIG. 1B is a schematic view of a unit cell of the semiconductor device, in accordance with some embodiments of the present disclosure.

FIG. 1C is a schematic view of a unit cell with two fuses of the semiconductor device, in accordance with some embodiments of the present disclosure.

FIG. 2A is a top view of a main array of a semiconductor device, in accordance with some embodiments of the present disclosure.

FIG. 2B is a top view of a spare array of a semiconductor device, in accordance with some embodiments of the present disclosure.

FIG. 3A is a cross-sectional view of a semiconductor device, in accordance with some embodiments of the present disclosure.

FIG. 3B is another cross-sectional view of a semiconductor device, in accordance with some embodiments of the present disclosure.

FIG. 4 is a flowchart illustrating a method of manufacturing a semiconductor device, in accordance with some embodiments of the present disclosure.

FIG. 5A illustrates one or more stages of an exemplary method for manufacturing a semiconductor device according to some embodiments of the present disclosure.

FIG. 5B illustrates one or more stages of an exemplary method for manufacturing a semiconductor device according to some embodiments of the present disclosure.

FIG. 5C illustrates one or more stages of an exemplary method for manufacturing a semiconductor device according to some embodiments of the present disclosure.

FIG. 5D illustrates one or more stages of an exemplary method for manufacturing a semiconductor device according to some embodiments of the present disclosure.

FIG. 5E illustrates one or more stages of an exemplary method for manufacturing a semiconductor device according to some embodiments of the present disclosure.

FIG. 5F illustrates one or more stages of an exemplary method for manufacturing a semiconductor device according to some embodiments of the present disclosure.

FIG. 5G illustrates one or more stages of an exemplary method for manufacturing a semiconductor device according to some embodiments of the present disclosure.

FIG. 5H illustrates one or more stages of an exemplary method for manufacturing a semiconductor device according to some embodiments of the present disclosure.

FIG. 5I illustrates one or more stages of an exemplary method for manufacturing a semiconductor device according to some embodiments of the present disclosure.

FIG. 5J illustrates one or more stages of an exemplary method for manufacturing a semiconductor device according to some embodiments of the present disclosure.

FIG. 5K illustrates one or more stages of an exemplary method for manufacturing a semiconductor device according to some embodiments of the present disclosure.

FIG. 5L illustrates one or more stages of an exemplary method for manufacturing a semiconductor device according to some embodiments of the present disclosure.

FIG. 5M illustrates one or more stages of an exemplary method for manufacturing a semiconductor device according to some embodiments of the present disclosure.

FIG. 5N illustrates one or more stages of an exemplary method for manufacturing a semiconductor device according to some embodiments of the present disclosure.

FIG. 5O illustrates one or more stages of an exemplary method for manufacturing a semiconductor device according to some embodiments of the present disclosure.

FIG. 5P illustrates one or more stages of an exemplary method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

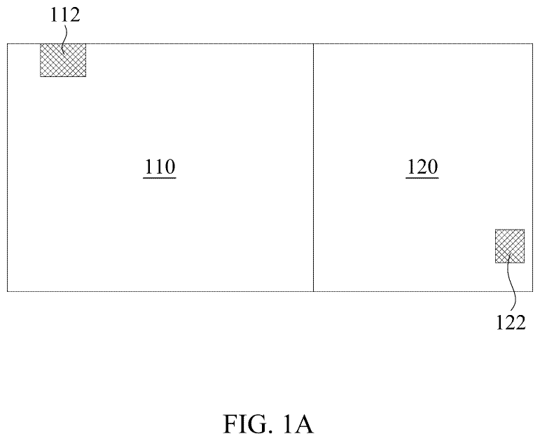

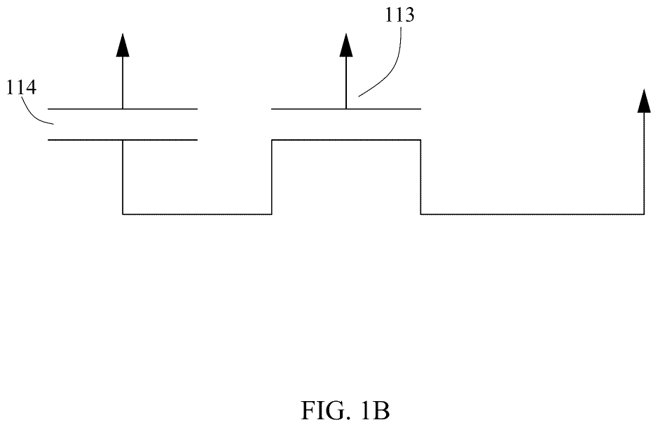

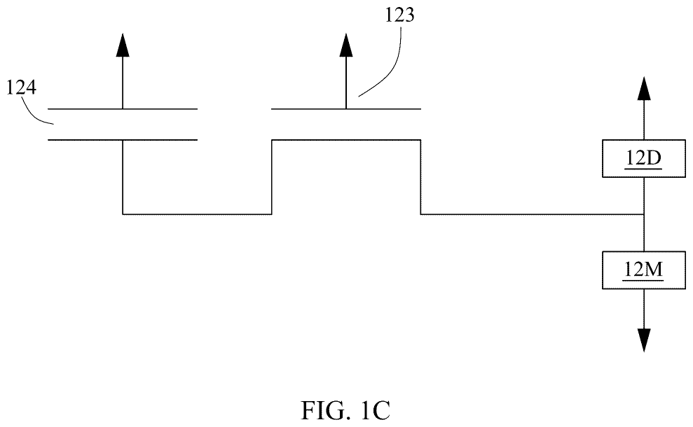

FIG. 1A is a top view of a semiconductor device 10, in accordance with some embodiments of the present disclosure. The semiconductor device 10 may include at least one cell region in which a memory device is formed. The memory device may include, for example, a dynamic random access memory (DRAM) device, a one-time programming (OTP) memory device, a static random access memory (SRAM) device, or other suitable memory devices. In some embodiments, a DRAM may include, for example, a transistor, a capacitor, and other components. During a read operation, a word line may be asserted, turning on the transistor. The enabled transistor allows the voltage across the capacitor to be read by a sense amplifier through a bit line. During a write operation, the data to be written may be provided on the bit line when the word line is asserted.

In some embodiments, the semiconductor device 10 may include a peripheral region (not shown) utilized to form a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices) or other devices.

In some embodiments, the semiconductor device 10 may include a main array 110 and a spare array 120. Each of the main array 110 and the spare array 120 may include several cell regions, and each of the cell regions can include one or more unit cells. As shown in FIG. 1A, the main array 110 includes a unit cell 112, and the spare array 120 includes a unit cell 122. The spare array 120 can be similar to the main array 110 in order to detect the performance and operation of the main array 110. In some embodiments, a redundant bit line can be provided for the spare array 120. A backside power line can be used for the spare array 120 as an isolated path for turning on the redundant bit line.

FIG. 1B is a schematic view of a unit cell 112 of the main array 110 the semiconductor device 10, in accordance with some embodiments of the present disclosure. The unit cell 112 can include a transistor 113 and a capacitor 114. The unit cell 112 can include a 1T1C cell. The capacitor 114 can be electrically connected to drain or source of the transistor 113. Source/drain region(s) may refer to a source or a drain, individually or collectively dependent upon the context.

FIG. 1C is a schematic view of a unit cell 122 with two fuses 12D and 12M of the spare array 120 of the semiconductor device 10, in accordance with some embodiments of the present disclosure. The unit cell 122 can include a transistor 123, a capacitor 124 and two fuses 12D and 12M. The unit cell 122 can include a 1T1C cell. The capacitor 124 can be electrically connected to drain or source of the transistor 123. The fuses 12D and 12M can be electrically connected to another drain or source of the transistor 123. As shown in FIG. 1C, the transistor 123 is electrically connected between the capacitor 124 and the two fuses 12D and 12M.

In some embodiments, the fuse 12D may include a dielectric fuse, and the dielectric fuse may include a dielectric layer. The fuse 12D may be normally off. The fuse 12D may be open circuit or electrically disconnected before being burned out by a high voltage or high current. In some embodiments, the fuse 12M may include a fuse metal, and the fuse metal may include a metal structure. The fuse 12M may be normally on. The fuse 12M may be short circuit or electrically connected before being burned out by a high voltage or high current. The fuse 12D can be electrically connected to the fuse 12M.

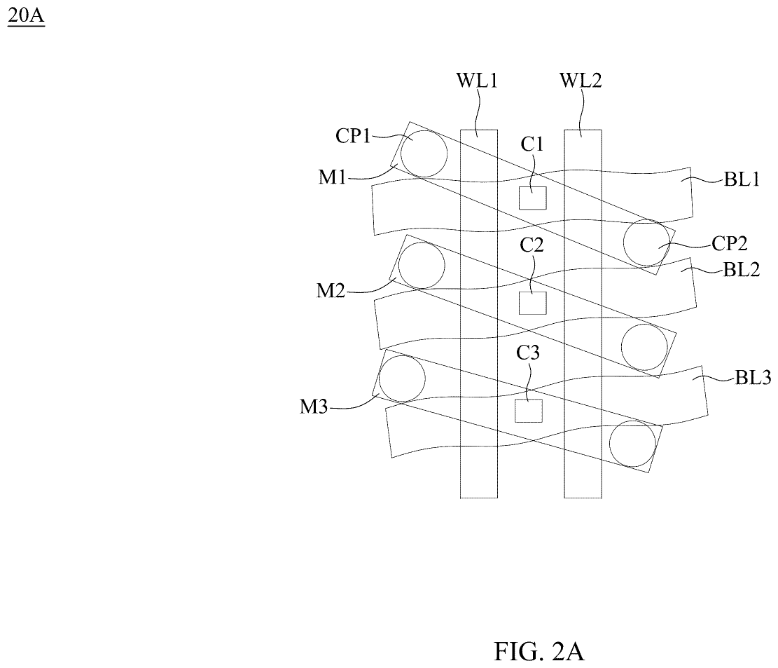

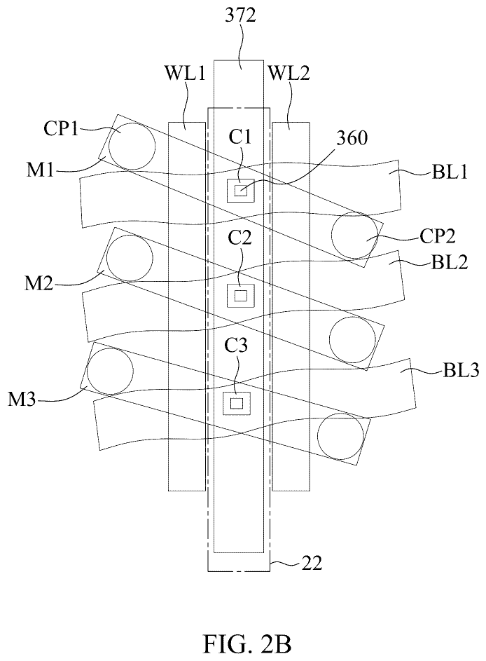

FIG. 2A is a top view of a main array of a semiconductor device 20A, in accordance with some embodiments of the present disclosure. The semiconductor device 20A of FIG. 2A can correspond to the main array 110 of the semiconductor device 10 of FIG. 1A.

The semiconductor device 20A may include bit lines BL1, BL2, BL3, word lines WL1, WL2, active areas M1, M2, M3, shield contacts C1, C2, C3, and capacitors CP1 and CP2. The bit lines BL1, BL2, and BL3 can be substantially vertical to the word lines WL1 and WL2. The capacitors CP1 and CP2 may be provided at two ends of the active area M1. The bit line BL1 may be electrically connected to the active area M1 through the shield contact C1. The bit line BL2 may be electrically connected to the active area M2 through the shield contact C2. The bit line BL3 may be electrically connected to the active area M3 through the shield contact C3.

Each of the bit lines BL1, BL2, BL3, and word lines WL1, WL2 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof. Each of the active areas M1, M2, M3 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonite; an alloy semiconductor material including at least one of SiGe, GaAsP, AlInAs, AlGaAs, GaInAs, GaInP, and GaInAsP; any other suitable materials; or a combination thereof. The active areas M1, M2, and M3 may include N-type dopants. The active areas M1, M2, and M3 may be doped with an N-type dopant such as phosphorus (P), arsenic (As), or antimony (Sb). Each of the shield contacts C1, C2, C3 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

FIG. 2B is a top view of a spare array of a semiconductor device 20B, in accordance with some embodiments of the present disclosure. The semiconductor device 20B of FIG. 2B can correspond to the spare array 120 of the semiconductor device 10 of FIG. 1A. Compared to the semiconductor device 20A, the semiconductor device 20B may include extra manufacturing process 22 to provide a redundant bit line in the spare array 120.

In some embodiments, the metal structure 372 can be provided between the word lines WL1 and WL2. The fuse metal 360 can be provided within the metal structure 372 and the shield contact C1 from the top view. In some embodiments, the metal structure 372 may correspond to or be included by the fuse 12D. In some embodiments, the fuse metal 360 may correspond to or be included by the fuse 12M. In some embodiments, the fuses 12D and 12M are used to provide the high voltage path and high current path in the spare array without affecting the main array. In some embodiments, the high voltage path can be generated to burn or blown out the fuse 12D. Afterwards, the fuse 12D may be burned or blown out, and it may become a short circuit for passing through currents. In some embodiments, the high current path can pass from the fuse 12D to blown or burn out the fuse 12M. Therefore, the fuses 12D and 12M can provide a bottom power line to blown out the redundant bit line and repair the semiconductor device 20B after assembly.

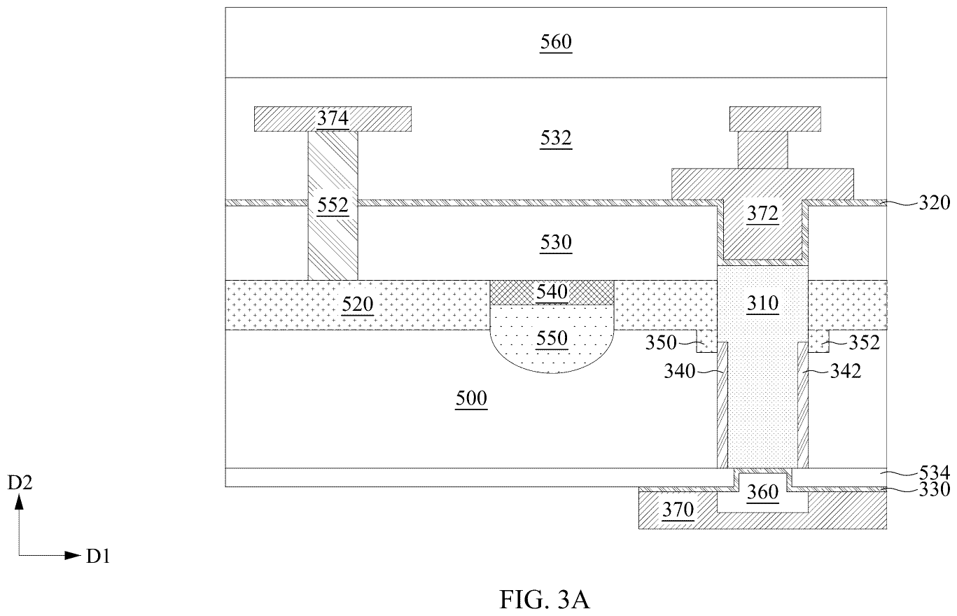

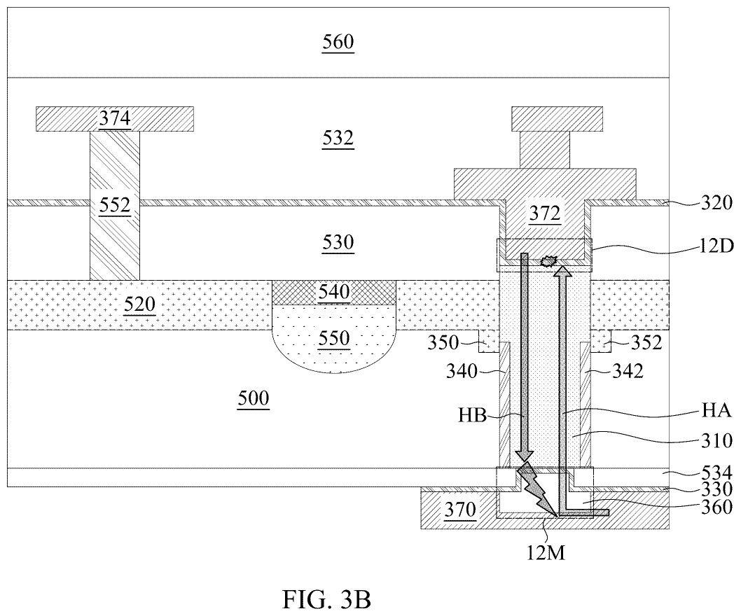

FIG. 3A is a cross-sectional view of a semiconductor device 30, in accordance with some embodiments of the present disclosure. The semiconductor device 20B of FIG. 2B can correspond to the spare array 120 of the semiconductor device 10 of FIG. 1A. The semiconductor device 30 may include a doped structure 310, two dielectric layers 320 and 330, three insulating structures 340 and 342 and 540, two doped portions 350 and 352, a fuse metal 360, three metal structures 370, 372 and 374, a well region 500, a doped layer 520, three oxidation layers 530, 532 and 534, a gate structure 550, a metal structure 552, and a bonding layer 560.

In some embodiments, the well region 500 can be formed above the oxidation layer 534. The well region 500 and the oxidation layer 534 may extend along D1 direction. The oxidation layer 534 may be formed between the dielectric layer 530 and the well region 500. The fuse metal 360 can be formed below and covered by the dielectric layer 330. The dielectric layer 330 may be formed above the fuse metal 360 and the metal structure 370. The fuse metal 360 can be surrounded by the dielectric layer 330 and the metal structure 370.

The insulating structures 340 and 342, and the well region 500 can be formed above the oxidation layer 534. The doped structure 310 can be formed above the dielectric layer 330. The doped structure 310 may be disposed above the dielectric layer 330 and below the dielectric layer 320. The doped structure 310 can extend along the D2 direction which is vertical to D1 direction. The insulating structures 340 and 342 can extend along the D2 direction. The doped structure 310 may be disposed between two insulating structures 340 and 342. The insulating structures 340 and 342 may be adjacent to or in direct contact with the lateral sides of the doped structure 310.

As shown in FIG. 3A, the doped layer 520 may be disposed above the well region 500. The doped layer 520 can extend along the D1 direction. The doped structure 310 may penetrate or be surrounded by the doped layer 520. In addition, the doped portion 350 can be formed below the doped layer 520 and within the well region 500. The doped portion 350 can be adjacent to or in direct contact with the lateral sides of the doped structure 310 and the insulating structure 340. The doped portion 350 may be surrounded by the doped layer 520, the doped structure 310, the insulating structure 340 and the well region 500. In addition, the doped portion 352 can be formed below the doped layer 520 and within the well region 500. The doped portion 352 can be adjacent to or in direct contact with the lateral sides of the doped structure 310 and the insulating structure 342. The doped portion 352 may be surrounded by the doped layer 520, the doped structure 310, the insulating structure 342 and the well region 500.

The gate structure 550 may be formed between the well region 500 and the doped layer 520. The gate structure 550 may be in a shape of semicircle toward the well region 500. An oxidation layer can be provided along the edge of the semicircle between the well region 500 and the doped layer 520. Furthermore, the insulating structure 540 may be disposed above the gate structure 550 along the D2 direction. The insulating structure 540 and the gate structure 550 may be surrounded by the doped layer 520 and the well region 500. The top surfaces of the insulating structure 540 and the doped layer 520 are at the same escalation level. The top surfaces of the doped structure 310 can be higher than the top surfaces of the insulating structure 540 and the doped layer 520.

The oxidation layer 530 can be formed above the doped layer 520 and the insulating structure 540. The oxidation layer 530 can extend along the D1 direction. The dielectric layer 320 may be disposed above the oxidation layer 530 and the doped structure 310. The dielectric layer 320 may include a recess structure for accommodating the metal structure 372. The metal structure 372 may be formed above the dielectric layer 320. In addition, the metal structure 552 can be disposed above the doped layer 520. The metal structure 552 can extend along the D2 direction and penetrate the dielectric layer 320 and the oxidation layer 530. The metal structure 374 may be disposed above the metal structure 552.

In some embodiments, the oxidation layer 532 may be disposed above the dielectric layer 320 and the metal structure 372. The oxidation layer 532 may extend along the D1 direction. The metal structures 372 and 374 may be formed within or surrounded by the oxidation layer 532. The bonding layer 560 may be formed above the oxidation layer 532. The bonding layer 560 may extend along the D1 direction.

FIG. 3B is another cross-sectional view of a semiconductor device 30, in accordance with some embodiments of the present disclosure. The semiconductor device 30 of FIG. 3B can be similar to the embodiment of FIG. 3A, except for the high voltage path HA, the high current path HB, and the two fuses 12D and 12M described as follows.

In some embodiments, the fuse 12D can at least include the dielectric layer 320 formed between the metal structure 372 and the doped structure 310. The fuse 12M can at least include the fuse metal 360 formed between the dielectric layer 330 and the metal structure 370.

During the back end of line (BEOL) process of manufacturing the semiconductor device 30, weak bits may occur to affect the functional and performance of the memory device. However, it may be difficult to obtain the high voltage for burning or blowing out the fuse, since the semiconductor device 30 may have been assembled and mounted on a printed circuit board. Accordingly, it becomes inconvenient to implement the testing and repairing for the semiconductor device 30.

The present disclosure provides the semiconductor device 30 of the spare array which is isolated to the main array. By utilizing the two fuses 12D and 12M, the high voltage path HA and the high current path HB can be created without affecting the main array. In some embodiments, the high voltage path HA can be generated from the back side of the semiconductor device 300, and the high voltage path HA can burn or blown out the fuse 12D. Afterwards, the fuse 12D may be burned or blown out, and it may become a short circuit for passing through currents. In some embodiments, the high current path HB can pass from the fuse 12D to the fuse 12M. The fuse 12M can be blown or burned out by the high current path HB, and it may become an open circuit for burning the redundant bit line and repairing the semiconductor device 30 after assembly.

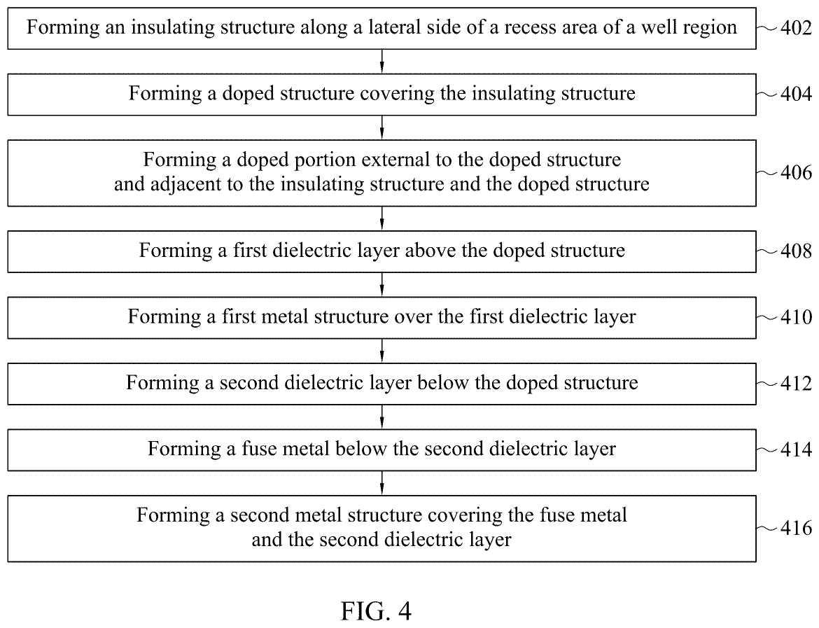

FIG. 4 is a flowchart illustrating a method 40 of manufacturing a semiconductor device 30, in accordance with some embodiments of the present disclosure.

The method 40 may begin with an operation 402 in which an insulating structure may be formed along a lateral side of a recess area of a well region. The method 400 may continue with an operation 404 in which a doped structure may be formed to cover the insulating structure. The method 400 may continue with an operation 406 in which a doped portion may be formed external to the doped structure and adjacent to the insulating structure and the doped structure.

In some embodiments, the method 400 may continue with an operation 408 in which a first dielectric layer may be formed above the doped structure. The method 400 may continue with an operation 410 in which a first metal structure may be formed over the first dielectric layer. The method 400 may continue with an operation 412 in which a second dielectric layer may be formed below the doped structure. The method 400 may continue with an operation 414 in which a fuse metal may be formed below the second dielectric layer. The method 400 may continue with an operation 416 in which a second metal structure may be formed to cover the fuse metal and the second dielectric layer.

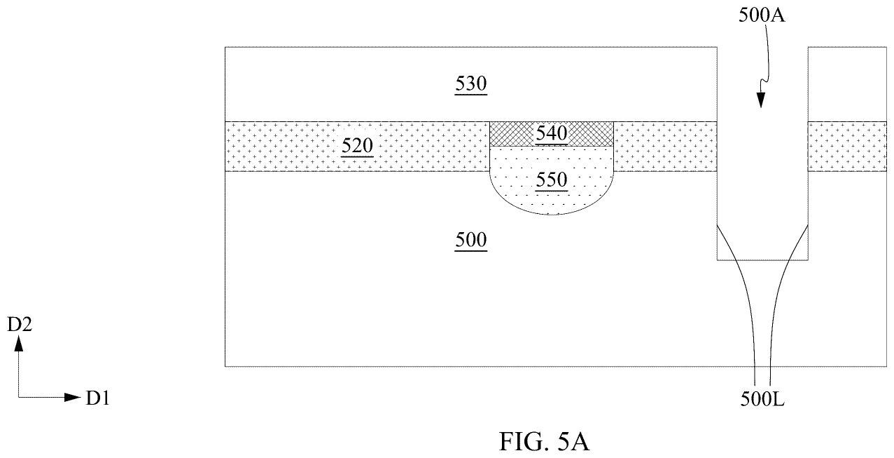

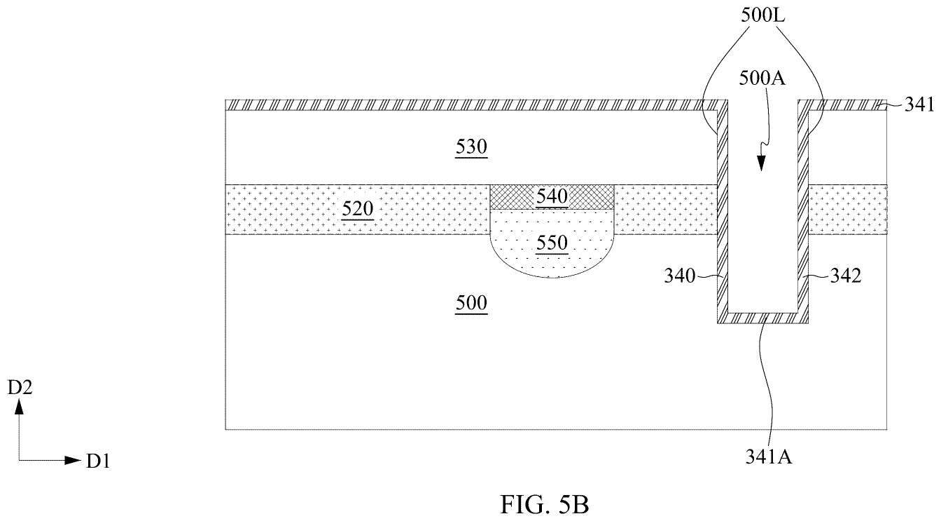

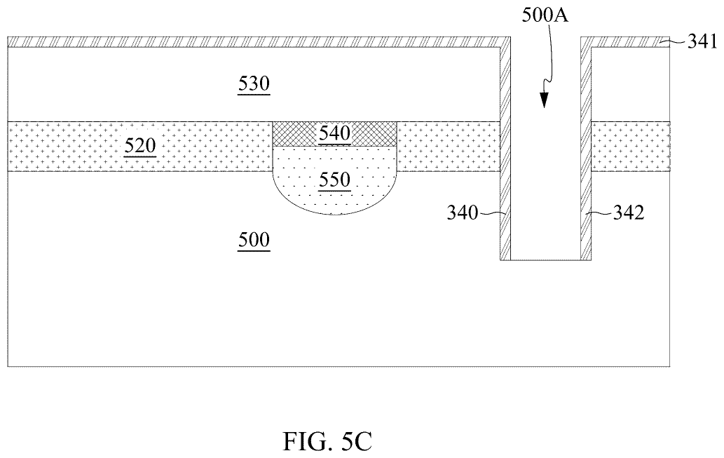

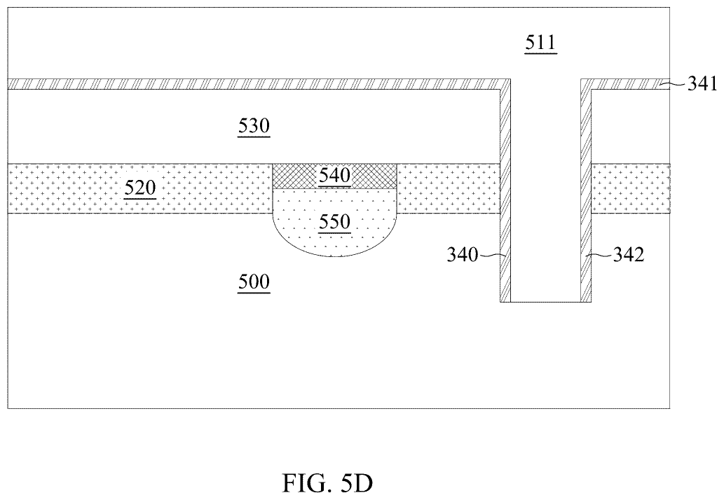

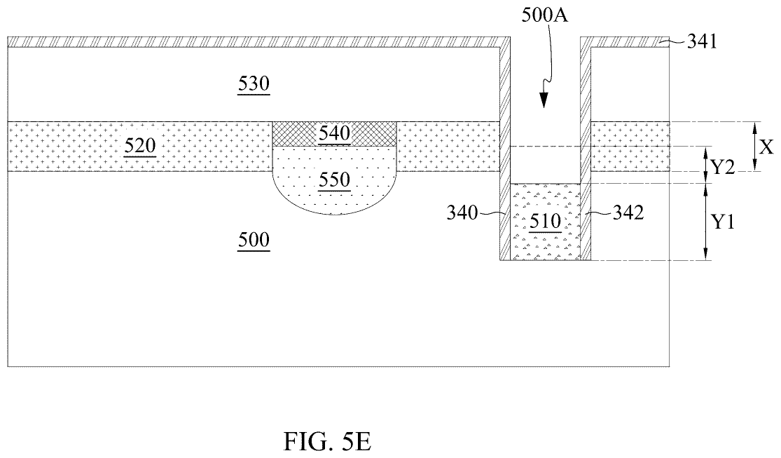

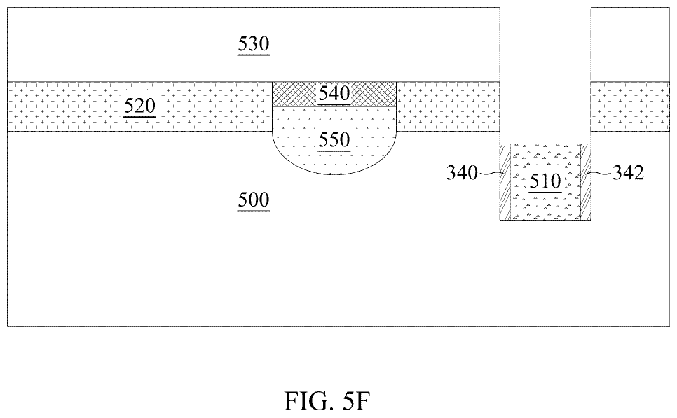

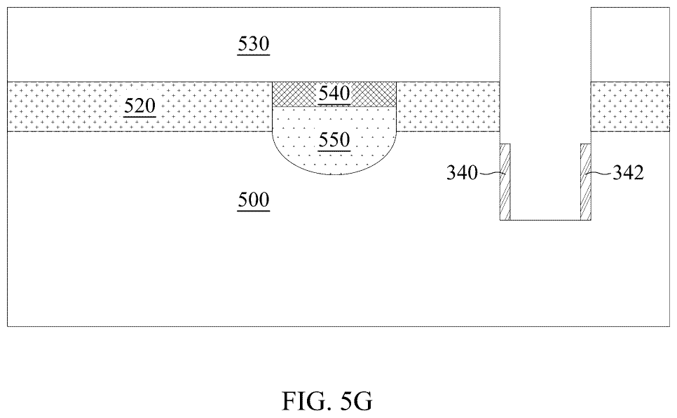

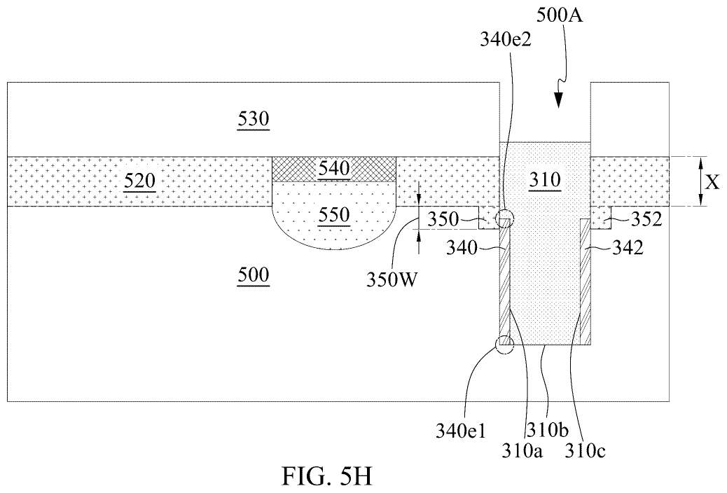

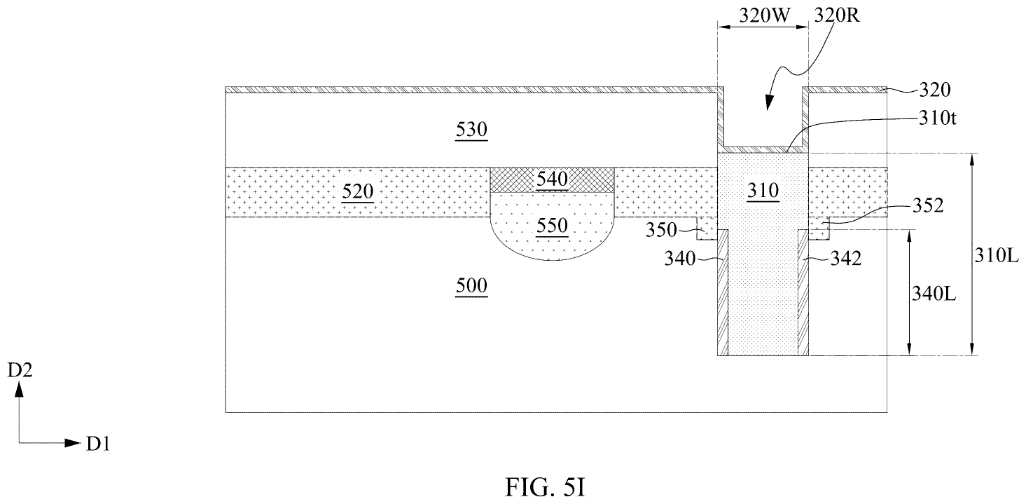

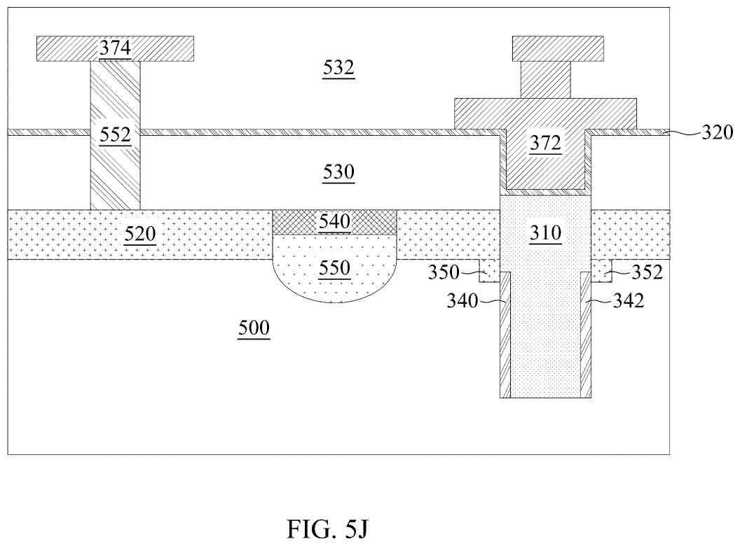

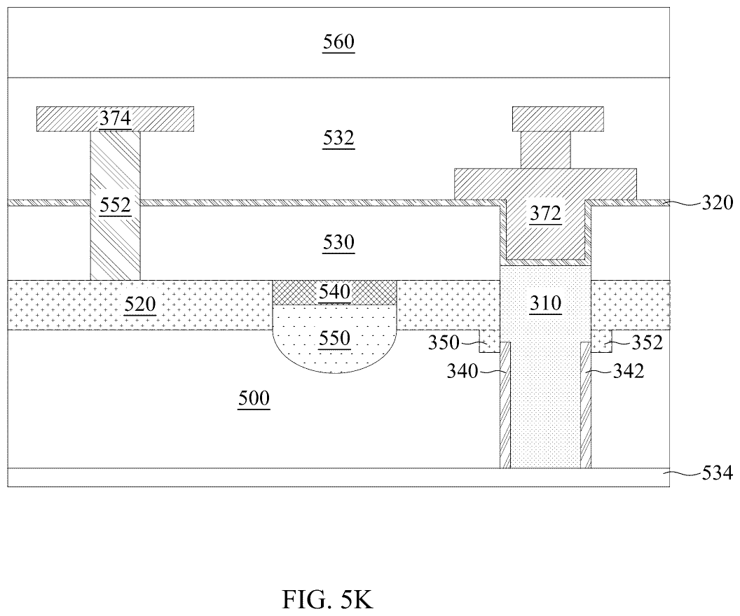

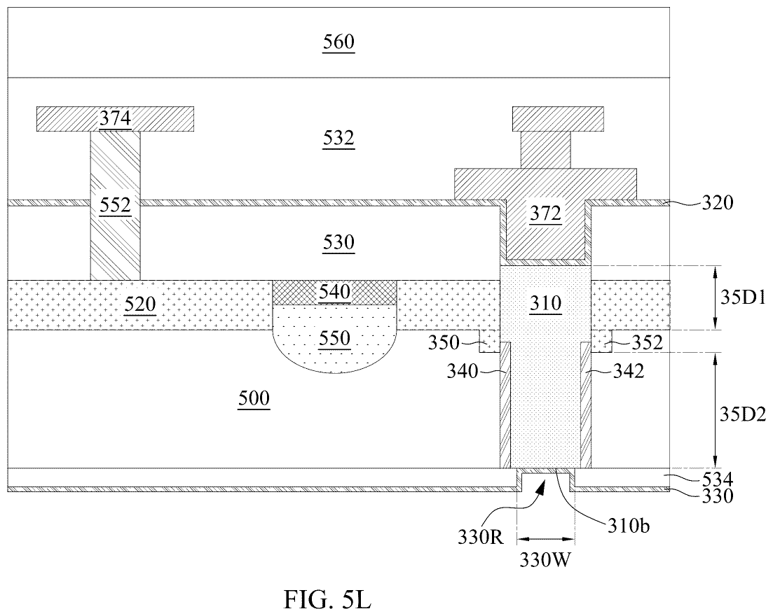

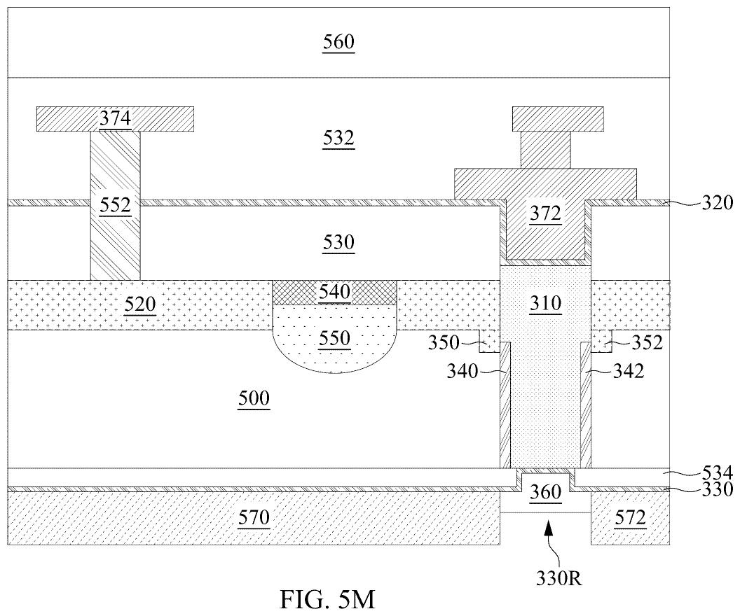

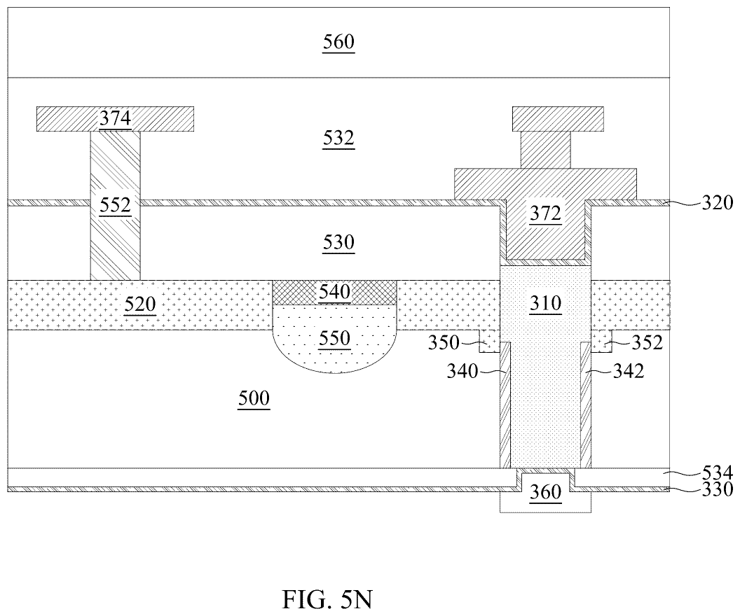

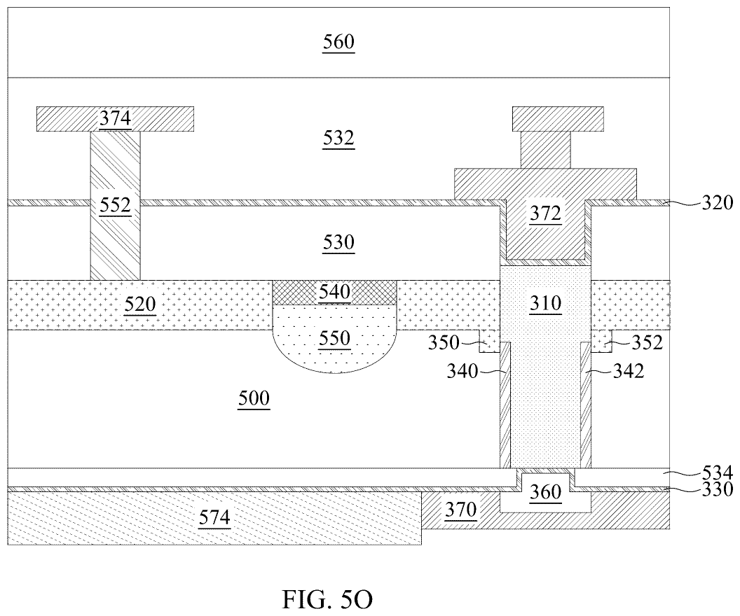

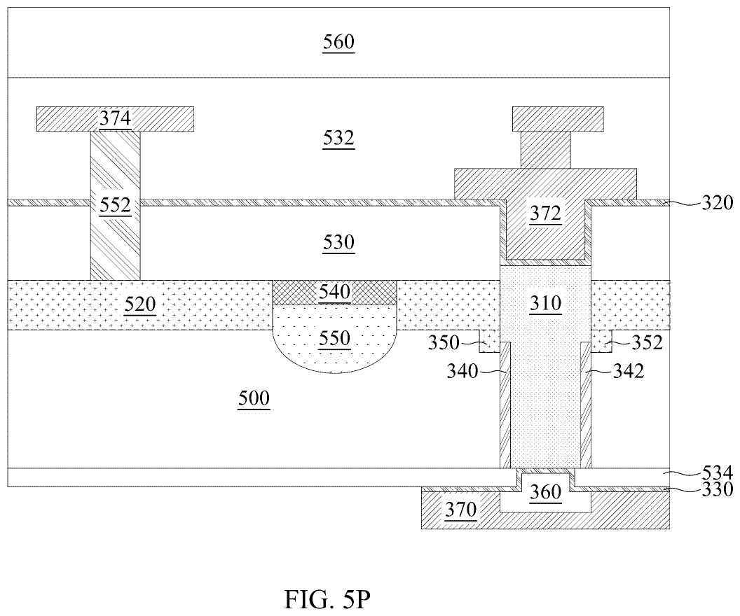

FIG. 5A illustrates one or more stages of an exemplary method for manufacturing a semiconductor device according to some embodiments of the present disclosure. The well region 500 can extend along the D1 direction. The well region 500 may include a P-type well region. The well region 500 may include P-type dopants. The well region 500 may be doped with a P-type dopant such as boron (B) or indium (In). The well region 500 may be formed on or within a substrate (not shown). The substrate may be a semiconductor substrate, such as a bulk semiconductor, a semiconductor-on-insulator (SOI) substrate, or the like. The substrate may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonite; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate may have a multilayered structure, or the substrate may include a multilayered compound semiconductor structure.

The doped layer 520 may be formed on the well region 500. The doped layer 520 can extend along the D1 direction. The doped layer 520 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonite; an alloy semiconductor material including at least one of SiGe, GaAsP, AlInAs, AlGaAs, GaInAs, GaInP, and GaInAsP; any other suitable materials; or a combination thereof. The doped layer 520 may include N-type dopants. The doped layer 520 may be doped with an N-type dopant such as phosphorus (P), arsenic (As), or antimony (Sb).

The oxidation layer 530 may be disposed on the doped layer 520. The oxidation layer 530 can extend along the D1 direction. In some embodiments, the oxidation layer 530 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process. The oxidation layer 530 may include, for example, silicon oxide (SiO₂), silicon nitride (Si₃N₄), silicon oxynitride (N₂OSi₂), silicon nitride oxide (N₂OSi₂), or other suitable materials.

As shown in FIG. 5A, the insulating structure 540 and the gate structure 550 may be formed within the doped layer 520 and the well region 500. The gate structure 550 may include a recess gate. The insulating structure 540 can be formed on the gate structure 550. The insulating structure 540 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability. The insulating structure 540 may include, for example, silicon oxide, silicon nitride, silicon oxynitride, silicon nitride oxide, a high-k material or combinations thereof.

In some embodiments, a recess area 500A may be formed as shown in FIG. 5A. The recess area 500A may be formed by etching some portions of the doped layer 520, the oxidation layer 530 and the well region 500. The recess area 500A may have two lateral surfaces 500L along the D2 direction. The recess area 500A may serve as a redundant bit line contact. The recess area 500A may be spaced apart or separated from the gate structure 550. The etching may include one or more stages, and each of the stages may be configured to etch through at least one material.

FIG. 5B illustrates one or more stages of an exemplary method for manufacturing a semiconductor device according to some embodiments of the present disclosure. The insulating layer may be disposed above the oxidation layer 530 and the recess area 500A of the well region 500. As shown in FIG. 5B, the insulating layer can include several insulating structures 340, 341, 342 and 341A. In some embodiments, the insulating structure 341 may be disposed on the oxidation layer. The insulating structures 340 and 342 may be disposed adjacent to the lateral surfaces 500L of the recess area 500A of the well region 500. The insulating structure 341A may be disposed on the bottom of the recess area 500A of the well region 500.

The insulating structures 340, 341, 342 and 341A may include, for example, silicon oxide, silicon nitride, silicon oxynitride, silicon nitride oxide, or combinations thereof. In some embodiments, the insulating structures 340, 341, 342 and 341A may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process.

FIG. 5C illustrates one or more stages of an exemplary method for manufacturing a semiconductor device according to some embodiments of the present disclosure. The insulating structure 341A can be removed from the bottom of the recess area 500A. The insulating structure 341A may be removed by etching. The insulating structure 341A may be removed by dry etching. The etching may include one or more stages, and each of the stages may be configured to etch through at least one material.

FIG. 5D illustrates one or more stages of an exemplary method for manufacturing a semiconductor device according to some embodiments of the present disclosure. The spin-on carbon (SOC) layer 511 may be formed on the insulating structure 341. The recess area 500A may be filled with the SOC layer 511. The SOC layer 511 may be formed by, for example, coating (e.g., spin-on coating), printing, or other suitable processes. The SOC layer 511 may be patterned by, for example, soft baking, mask aligning, exposure, post-exposure baking, developing the photoresist, rinsing and drying (e.g., hard baking). The SOC layer 511 may include polymer materials with high carbon content.

FIG. 5E illustrates one or more stages of an exemplary method for manufacturing a semiconductor device according to some embodiments of the present disclosure. In some embodiments, some portions of the SOC layer 511 of FIG. 5D can be removed to leave the remaining SOC structure 510 on the bottom portion of the recess area 500A. The material of the SOC structure 510 can be substantially identical to the material of the SOC layer 511. The SOC layer 511 may be removed by etching to form the SOC structure 510. The SOC layer 511 may be removed by dry etching to form the SOC structure 510. The etching may include one or more stages, and each of the stages may be configured to etch through at least one material.

In some embodiments, the doped layer 520 may have a thickness X. The depth of the SOC structure 510 is Y1. By adjusting the etching process associated with the n-type dopant of the doped layer 520, the depth of the SOC structure can be increased by the depth Y2. The depth of the SOC structure can be increased to the summation of the depths Y1 and Y2. In some embodiments, the depth Y1 can be substantially equal to the thickness X. In some embodiments, the depth Y1 can be greater than the thickness X. In some embodiments, the depth Y1 can be less than the thickness X.

In some embodiments, the depth Y2 can be substantially equal to 20% of the thickness X. In some embodiments, the depth Y2 can be less than 20% of the thickness X. In some embodiments, the depth Y2 can be substantially equal to 10% of the thickness X. In some embodiments, the depth Y2 can be less than 10% of the thickness X. In some embodiments, the depth Y2 can be substantially equal to 5% of the thickness X. In some embodiments, the depth Y2 can be less than 5% of the thickness X.

FIG. 5F illustrates one or more stages of an exemplary method for manufacturing a semiconductor device according to some embodiments of the present disclosure. The SOC structure 510 can be used as a block for etching the insulating structures 340, 341, and 342. In some embodiments, the insulating structure 341 may be stripped or removed by dry etching. A portion of the insulating structure 340 may be stripped or removed by dry etching. A portion of the insulating structure 342 may be stripped or removed by dry etching. The remaining insulating structures 340 and 342 adjacent to or in contact with the SOC structure 510 may not be stripped.

FIG. 5G illustrates one or more stages of an exemplary method for manufacturing a semiconductor device according to some embodiments of the present disclosure. In some embodiments, the SOC structure 510 between the insulating structures 340 and 342 can be removed or stripped. The SOC structure 510 between the insulating structures 340 and 342 can be removed by etching. The SOC structure 510 between the insulating structures 340 and 342 can be removed by dry etching.

FIG. 5H illustrates one or more stages of an exemplary method for manufacturing a semiconductor device according to some embodiments of the present disclosure. The doped structure 310 may be disposed in the recess area 500A. The doped structure 310 may be formed by deposition and annealing. The doped structure 310 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonite; an alloy semiconductor material including at least one of SiGe, GaAsP, AlInAs, AlGaAs, GaInAs, GaInP, and GaInAsP; any other suitable materials; or a combination thereof.

In some embodiments, the doped structure 310 may be doped with an N-type dopant such as phosphorus (P), arsenic (As), or antimony (Sb). In some embodiments, the dopant concentration of the doped structure 310 can be greater than the dopant concentration of the doped layer 520. In some embodiments, the dopant type of the doped structure 310 can be identical to the dopant type of the doped layer 520.

As shown in FIG. 5H, the doped structure 310 can be surrounded by the doped layer 520. The doped structure 310 can be surrounded by the well region 500 and the insulating structures 340 and 342. In some embodiments, the bottom surface 310b of the doped structure 310 may be in direct contact with the well region 500. In some embodiments, the lateral surface 310a of the doped structure 310 may be in direct contact with the insulating structure 340. In some embodiments, the lateral surface 310c of the doped structure 310 may be in direct contact with the insulating structure 342. In some embodiments, the doped structure 310 may be exposed from the doped layer 530. The doped structure 310 and the insulating structures 340 and 342 can be formed in a rectangular shape within the recess area 500A.

In some embodiments, a doped portion 350 may be formed adjacent to the doped structure 310 and the insulating structure 340. A doped portion 352 may be formed adjacent to the doped structure 310 and the insulating structure 342. The doped portions 350 and 352 may be formed by diffusion of N-type dopant from the doped layer 520. In some embodiments, the doped portions 350 and 352 may be used to provide an electrical path with low resistance for the fuse 12D as shown in FIG. 3B. In some embodiments, the doped portions 350 and 352 may be used to provide the fuse 12D with high electrical field for blowing or burning out.

The doped portions 350 and 352 and the doped layer 520 may have substantially the same material. The doped portions 350 and 352 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonite; an alloy semiconductor material including at least one of SiGe, GaAsP, AlInAs, AlGaAs, GaInAs, GaInP, and GaInAsP; any other suitable materials; or a combination thereof.

In some embodiments, the doped portions 350 and 352 may be doped with an N-type dopant such as phosphorus (P), arsenic (As), or antimony (Sb). In some embodiments, the dopant concentration of the doped portions 350 and 352 can be greater than the dopant concentration of the doped layer 520. In some embodiments, the dopant concentration of the doped portions 350 and 352 can be greater than the dopant concentration of the doped structure 310. In some embodiments, the dopant concentration of the doped portions 350 and 352 can be less than the dopant concentration of the doped structure 310. In some embodiments, the dopant concentration of the doped portions 350 and 352 can be substantially identical to the dopant concentration of the doped structure 310. In some embodiments, the dopant type of the doped portions 350 and 352 can be identical to the dopant type of the doped layer 520. In some embodiments, the dopant type of the doped portions 350 and 352 can be identical to the dopant type of the doped structure 310.

As shown in FIG. 5H, the doped portion 350 may be formed within the well region 500 and below the doped layer 520. The doped portion 350 may be surrounded by the doped structure 310, the insulating structure 340, the well region 500 and the doped layer 520. The end 340e2 of the insulating structure 340 can be in direct contact with the doped structure 310 and close to the doped portion 350. The end 340e1 of the insulating structure 340 can be at the same escalation level with the bottom surface 310b of the doped structure 310.

The doped portion 352 may be formed within the well region 500 and below the doped layer 520. The doped portion 352 may be surrounded by the doped structure 310, the insulating structure 342, the well region 500 and the doped layer 520. The top end of the insulating structure 342 can be in direct contact with the doped structure 310 and close to the doped portion 350. The bottom end of the insulating structure 342 can be at the same escalation level with the bottom surface 310b of the doped structure 310.

In some embodiments, the doped portions 350 and 352 may have substantially the same size of 350W. The doped portions 350 and 352 may have substantially the same shape. In some embodiments, the size 350W of each of the doped portions 350 and 352 can be substantially equal to 20% or one fifth of the thickness X of the doped layer 520. In some embodiments, the size 350W of each of the doped portions 350 and 352 can be substantially less than 20% or one fifth of the thickness X of the doped layer 520. In some embodiments, the size 350W of each of the doped portions 350 and 352 can be substantially equal to 10% of the thickness X of the doped layer 520. In some embodiments, the size 350W of each of the doped portions 350 and 352 can be substantially less than 10% of the thickness X of the doped layer 520. In some embodiments, the size 350W of each of the doped portions 350 and 352 can be substantially equal to 5% of the thickness X of the doped layer 520. In some embodiments, the size 350W of each of the doped portions 350 and 352 can be substantially less than 5% of the thickness X of the doped layer 520.

FIG. 5I illustrates one or more stages of an exemplary method for manufacturing a semiconductor device according to some embodiments of the present disclosure. The dielectric layer 320 can be disposed on the oxidation layer 530 and the doped structure 310. In some embodiments, the dielectric layer 320 may include, for example, silicon oxide (SiO₂), silicon nitride (Si₃N₄), silicon oxynitride (N₂OSi₂), silicon nitride oxide (N₂OSi₂), a high-k material or combinations thereof. Examples of the high-k material include a dielectric material having a dielectric constant exceeding that of silicon dioxide (SiO₂), or a dielectric material having a dielectric constant higher than about 3.9. In some embodiments, the dielectric layer 320 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof. In some embodiments, the dielectric layer 320 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process.

In some embodiments, the dielectric layer 320 may extend along the D1 direction. In some embodiments, the dielectric layer 320 may include a continuous pattern or shape. The dielectric layer 320 may be in direct contact with the top surfaces of the oxidation layer 530 and the doped structure 310. The dielectric layer 320 may include a recess structure 320R above the doped structure 310. The recess structure 320R may have a width 320W along the D1 direction. In some embodiments, the width 320W of the recess structure 320R can be smaller than the length 340L of the insulating structures 340 and 342. In some embodiments, the width 320W of the recess structure 320R can be substantially equal to the length 340L of the insulating structures 340 and 342. In some embodiments, the width 320W of the recess structure 320R can be greater than the size of the doped portions 350 and 352. In some embodiments, the width 320W of the recess structure 320R can be smaller than the length 310L of the doped structure 310. In some embodiments, the length 340L of the insulating structures 340 and 342 can be smaller than the length 310L of the doped structure 310.

FIG. 5J illustrates one or more stages of an exemplary method for manufacturing a semiconductor device according to some embodiments of the present disclosure. The metal structure 372 may be disposed on the dielectric layer 320 and above the doped structure 310. The metal structure 372 may be accommodated by the recess structure of the dielectric layer 320. The metal structure 372 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

In some embodiments, the metal structure 552 may be disposed on the doped layer 520. The metal structure 372 may penetrate the dielectric layer 320. The metal structure 372 may extend along the D2 direction. The metal structure 552 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

As shown in FIG. 5J, the metal structure 374 may be disposed on the metal structure 552. The metal structure 374 may be spaced apart from the metal structure 372. The metal structure 374 may extend along the D1 direction. The metal structure 374 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

In some embodiments, the oxidation layer 532 may be formed or disposed on the dielectric layer 3203. The oxidation layer 532 may cover the metal structures 372, 374 and 552. The oxidation layer 532 can extend along the D1 direction. The oxidation layer 532 and the metal structures 374 and 552 may be used to form or provide a capacitor. In some embodiments, the oxidation layer 532 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process. The oxidation layer 530 may include, for example, silicon oxide (SiO₂), silicon nitride (Si₃N₄), silicon oxynitride (N₂OSi₂), silicon nitride oxide (N₂OSi₂), or other suitable materials.

FIG. 5K illustrates one or more stages of an exemplary method for manufacturing a semiconductor device according to some embodiments of the present disclosure. The bonding layer 560 may be formed or bonded on the oxidation layer 532 for backside grinding. The bonding layer 560 may include, for example, silicon, silicon oxide, silicon nitride, silicon oxynitride, silicon nitride oxide, an insulating material or combinations thereof.

In some embodiments, backside grinding may be performed for thinning the well region 500, the doped structure 310, and the insulating structures 340 and 342. After the backside grinding, the bottom surfaces of the well region 500, the doped structure 310, and the insulating structures 340 and 342 can be substantially at the same escalation level. In some embodiments, the oxidation layer 534 can be formed below or in direct contact with the bottom surfaces of the well region 500, the doped structure 310, and the insulating structures 340 and 342. In some embodiments, the oxidation layer 534 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process. The oxidation layer 534 may include, for example, silicon oxide (SiO₂), silicon nitride (Si₃N₄), silicon oxynitride (N₂OSi₂), silicon nitride oxide (N₂OSi₂), or other suitable materials.

FIG. 5L illustrates one or more stages of an exemplary method for manufacturing a semiconductor device according to some embodiments of the present disclosure. Lithography operation may be executed on the oxidation layer 534 to form the dielectric layer 330. The dielectric layer 330 can be disposed below the oxidation layer 534 and the doped structure 310. In some embodiments, the dielectric layer 330 may include, for example, silicon oxide (SiO₂), silicon nitride (Si₃N₄), silicon oxynitride (N₂OSi₂), silicon nitride oxide (N₂OSi₂), a high-k material or combinations thereof. Examples of the high-k material include a dielectric material having a dielectric constant exceeding that of silicon dioxide (SiO₂), or a dielectric material having a dielectric constant higher than about 3.9. In some embodiments, the dielectric layer 330 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof. In some embodiments, the dielectric layer 320 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process.

In some embodiments, the dielectric layer 330 may extend along the D1 direction. In some embodiments, the dielectric layer 330 may include a continuous pattern or shape. The dielectric layer 330 may be in direct contact with the bottom surfaces of the oxidation layer 534 and the doped structure 310. The dielectric layer 330 may include a recess structure 330R below the doped structure 310. The recess structure 330R may have a width 330W along the D1 direction. In some embodiments, the width 330W of the recess structure 330R can be smaller than the length of the insulating structures 340 and 342. In some embodiments, the width 330W of the recess structure 330R can be substantially equal to the length of the insulating structures 340 and 342. In some embodiments, the width 330W of the recess structure 330R can be greater than the size of the doped portions 350 and 352. In some embodiments, the width 330W of the recess structure 330R can be smaller than the length of the doped structure 310.

In some embodiments, the distance 35D1 between the dielectric layer 320 and the doped portions 350 and 352 can be smaller than the distance 35D2 between the dielectric layer 330 and the doped portions 350 and 352. In some embodiments, the width 330W of the recess structure 330R can be smaller than the distance 35D1 between the dielectric layer 320 and the doped portions 350 and 352. In some embodiments, the width 330W of the recess structure 330R can be substantially identical to the distance 35D1 between the dielectric layer 320 and the doped portions 350 and 352. In some embodiments, the width 330W of the recess structure 330R can be greater than the distance 35D1 between the dielectric layer 320 and the doped portions 350 and 352.

FIG. 5M illustrates one or more stages of an exemplary method for manufacturing a semiconductor device according to some embodiments of the present disclosure. The fuse metal 360 can be formed or planted by utilizing the photosensitive layers 570 and 572. The photosensitive layers 570 and 572 may include a photoresist or other suitable materials. The photosensitive layers 570 and 572 may be patterned to expose a portion of the dielectric layer 330. The photosensitive layers 570 and 572 may be formed by, for example, coating (e.g., spin-on coating), printing, or other suitable processes. The photosensitive layers 570 and 572 may be patterned by, for example, soft baking, mask aligning, exposure, post-exposure baking, developing the photoresist, rinsing and drying (e.g., hard baking).

In some embodiments, the fuse metal 360 can be formed or planted below the dielectric layer 330 and the doped structure 310. The recess structure 330R of the dielectric layer 330 can be filled with the fuse metal 360. The fuse metal 360 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

FIG. 5N illustrates one or more stages of an exemplary method for manufacturing a semiconductor device according to some embodiments of the present disclosure. The photosensitive layers 570 and 572 may be removed or stripped to expose the fuse metal 360. The size and shape of the fuse metal 360 can be defined by the photosensitive layers 570 and 572.

FIG. 5O illustrates one or more stages of an exemplary method for manufacturing a semiconductor device according to some embodiments of the present disclosure. The photosensitive layer 574 may be formed below the dielectric layer 330. The photosensitive layer 574 may include a photoresist or other suitable materials. In some embodiments, the photosensitive layer 574 may be patterned to form or plant the metal structure 370. The photosensitive layer 574 may be formed by, for example, coating (e.g., spin-on coating), printing, or other suitable processes. The photosensitive layer 574 may be patterned by, for example, soft baking, mask aligning, exposure, post-exposure baking, developing the photoresist, rinsing and drying (e.g., hard baking).

As shown in FIG. 5O, the metal structure 370 can be formed or planted below the dielectric layer 330 and the fuse metal 360. The recess structure 330R of the dielectric layer 330 can be filled with the fuse metal 360 and the metal structure 370. The fuse metal 360 may be surrounded by the dielectric layer 330 and the metal structure 370. The metal structure 370 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability. In some embodiments, the melting point of the fuse metal 360 can be lower than the melting point of the metal structure 370.

FIG. 5P illustrates one or more stages of an exemplary method for manufacturing a semiconductor device according to some embodiments of the present disclosure. The photosensitive layer 574 may be removed or stripped to expose the metal structure 370. The size and thickness of the metal structure 370 can be defined by the photosensitive layer 574.

One aspect of the present disclosure provides a semiconductor device. The semiconductor device includes a doped structure, a first dielectric layer, a second dielectric layer and a first insulating structure. The first dielectric layer extends along a first direction and is disposed on a top surface of the doped structure along a second direction vertical to the first direction. The second dielectric layer is provided below a bottom surface of the doped structure along the second direction. The first insulating structure extends along the second direction and disposed adjacent to a lateral surface of the doped structure. A first end of the first insulating structure is at the same escalation level with the bottom surface of the doped structure, and length of the first insulating structure is smaller than length of the doped structure.

Another aspect of the present disclosure provides a semiconductor device. The semiconductor device includes a fuse metal, a doped structure, a first dielectric layer, a second dielectric layer and two doped portions. The first dielectric layer extends along a first direction and disposed above the fuse metal. The first dielectric layer comprises a first recess structure for accommodating the fuse metal. The doped structure is formed above the first dielectric layer and extends along a second direction vertical to the first direction. The second dielectric layer extends along the first direction and is disposed above the doped structure. The doped portions are adjacent to two lateral surfaces of the doped structure, and the doped portions are spaced apart from the first dielectric layer and the second dielectric layer.

Another aspect of the present disclosure provides a method of manufacturing a semiconductor device. The method includes: forming an insulating structure along a lateral side of a recess area of a well region; forming a doped structure covering the insulating structure, wherein the doped structure is longer than the insulating structure, and the insulating structure is between the well region and the doped structure; forming a doped portion external to the doped structure and adjacent to the insulating structure and the doped structure; forming a first dielectric layer above the doped structure; forming a second dielectric layer below the doped structure, wherein the doped portion is between and spaced apart from the first dielectric layer and the second dielectric layer; and forming a fuse metal below the second dielectric layer.

The embodiments of the present disclosure illustrate a semiconductor device including a capacitor component supported by an upper supporting frame and a lower supporting frame. The lower supporting frame defines an opening with a relatively large dimension (e.g., width or diameter) over the landing pad of the transistor, and the upper supporting frame defines the opening with a relatively small dimension (e.g., width or diameter). As a result, the leakage between abutting capacitor components can be prevented, while a relatively lower resistance can be achieved due to a larger contact area between the landing pad and the capacitor component. The material of the lower supporting frame can be different from that of the upper supporting frame to facilitate the formation of said opening.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a fuse metal;
a first dielectric layer, extending along a first direction and disposed above the fuse metal, wherein the first dielectric layer comprises a first recess structure for accommodating the fuse metal;
a doped structure, formed above the first dielectric layer and extending along a second direction vertical to the first direction;
a second dielectric layer, extending along the first direction and disposed above the doped structure; and
two doped portions, adjacent to two lateral surfaces of the doped structure, wherein the doped portions are spaced apart from the first dielectric layer and the second dielectric layer.

2. The semiconductor device of claim 1, wherein a distance between the doped portions and the second dielectric layer is less than that of the doped portions and the first dielectric layer.

3. The semiconductor device of claim 1, wherein the first dielectric layer and the second dielectric layer are in direct contact with the doped structure.

4. The semiconductor device of claim 1, further comprising:
a first metal structure, disposed below the fuse metal and the first dielectric layer, wherein the fuse metal is surrounded by the first metal structure and the first dielectric layer.

5. The semiconductor device of claim 4, further comprising:
a second metal structure, disposed above the second dielectric layer, wherein the second dielectric layer comprises a second recess structure for accommodating the second metal structure.

6. The semiconductor device of claim 1, further comprising:
two insulating structures, extending along the second direction and contacting the lateral surfaces of the doped structure, wherein the insulating structures are formed between the doped portions and the first dielectric layer along the second direction.

7. The semiconductor device of claim 6, wherein the insulating structures are spaced apart from the first dielectric layer and the second dielectric layer.

8. The semiconductor device of claim 6, further comprising:
a well region, extending along the first direction, wherein the insulating structures are formed between the doped structure and the well region; and
a doped layer, extending along the first direction and disposed on the well region, wherein the doped structure is surrounded by the insulating structures and the doped layer.

9. The semiconductor device of claim 8, wherein the doped portions are surrounded by the doped layer, the insulating structures, the doped structure and the well region.

10. The semiconductor device of claim 9, wherein size of each of the doped portions is less than one fifth of thickness of the doped layer.
